(19) United States
(12) Patent Application Publication
(10) Pub. No.: US 2024/0381735 A1
(43) Pub. Date: Nov. 14, 2024

(54) DISPLAY DEVICE AND METHOD OF FABRICATING THE SAME

(71) Applicant: SAMSUNG DISPLAY CO., LTD., YONGIN-SI (KR)

(72) Inventors: Woo Yong SUNG, YONGIN-SI (KR); Seung Yong SONG, YONGIN-SI (KR)

(21) Appl. No.: 18/525,760

(22) Filed: Nov. 30, 2023

(30) Foreign Application Priority Data
May 9, 2023 (KR) 10-2023-0060137

(51) Int. Cl. H10K 59/40; G06F 3/041; H10K 59/12; H10K 59/122; H10K 59/80

(52) U.S. Cl. CPC H10K 59/40; G06F 3/0412; H10K 59/1201; H10K 59/122; H10K 59/873; G06F 3/0446

(57) ABSTRACT

A display device includes a base layer that includes a first area and a second area, a light-emitting-element layer disposed on the base layer and that includes a light emitting element in the first area, an encapsulation layer disposed on the light-emitting-element layer, an organic insulating layer disposed on the encapsulation layer, where holes are formed in the organic insulating layer, an inorganic insulating layer disposed on the organic insulating layer, and touch electrodes disposed on the inorganic insulating layer.

### CROSS-REFERENCE TO RELATED APPLICATION

The present application claims priority under 35 U.S.C § 119 from Korean patent application number 10-2023-0060137, filed on May 9, 2023, the contents of which are herein incorporated by reference in their entirety.

### TECHNICAL FIELD

Various embodiments of the present disclosure are directed to a display device and a method of fabricating the display device. More particularly, various embodiments of the present disclosure are directed to a display device that includes a touch electrode, and a method of fabricating the display device.

### DISCUSSION OF THE RELATED ART

Electronic devices provided with touch panels that can indicate positions through touch are widely used. For example, with the proliferation of mobile electronic devices such as smartphones and tablet computers, touch panels have become widely used. As touch panels become more widely used, there is a growing need for technologies that can enhance the accuracy of touch detection and improve the response time for touch inputs.

The accuracy of touch detection can be enhanced by reducing influence of noise from signals generated by touch. Noise increases as the capacitance between a touch electrode and a cathode electrode increases. Research has been conducted to reduce the capacitance between the touch electrode and the cathode electrode by decreasing the permittivity of materials between the touch electrode and the cathode electrode. However, there are limitations in reducing the permittivity solely through changes in the materials between the touch electrode and the cathode electrode.

### SUMMARY

Various embodiments of the present disclosure are directed to a display device that includes holes.

Various embodiments of the present disclosure are directed to a method of fabricating a display device.

An embodiment of the present disclosure provides a display device that includes: a base layer that includes a first area and a second area; a light-emitting-element layer disposed on the base layer and that includes a light emitting element in the first area; an encapsulation layer disposed on the light-emitting-element layer; an organic insulating layer disposed on the encapsulation layer, where holes formed in the organic insulating layer; an inorganic insulating layer disposed on the organic insulating layer; and touch electrodes disposed on the inorganic insulating layer.

In an embodiment, the holes are formed in the second area.

In an embodiment, the holes have an air trap structure.

In an embodiment, the light-emitting-element layer further includes a pixel defining layer in the second area.

In an embodiment, each of the holes has a width of about 1 μm or less.

In an embodiment, a width of each of the holes is decreased as a resolution increases.

In an embodiment, a width of each of the holes in a second display area that has a second resolution is less than a width of each of the holes in first display area that has a first resolution that is less than the second resolution.

In an embodiment, the display device further includes a masking pattern disposed between the organic insulating layer and the inorganic insulating layer.

In an embodiment, the masking pattern overlaps a portion of at least one of the holes.

In an embodiment, the masking pattern is formed of inorganic material.

In an embodiment, the touch electrodes are formed of first conductive patterns and second conductive patterns that are disposed on the inorganic insulating layer. The first conductive patterns electrically connect some of the second conductive patterns.

An embodiment of the present disclosure provides a method of fabricating a display device that includes: forming a base layer that includes a first area and a second area; forming a light-emitting-element layer on the base layer where the light-emitting-element layer includes a light emitting element in the first area; forming an encapsulation layer on the light-emitting-element layer; forming an organic insulating layer on the encapsulation layer; forming a masking pattern on the organic insulating layer; forming holes in the organic insulating layer by etching the organic insulating layer; forming an inorganic insulating layer on the organic insulating layer; and forming touch electrodes on the inorganic insulating layer.

In an embodiment, the holes are formed in the second area.

In an embodiment, the inorganic insulating layer covers an upper portion of each of the holes of the organic insulating layer.

In an embodiment, the light-emitting-element layer further includes a pixel defining layer in the second area.

In an embodiment, each of the holes has a width of about 1 μm or less.

In an embodiment, the masking pattern is formed of a photoresist.

In an embodiment, the organic insulating layer is etched on a portion thereof that is exposed by the masking pattern.

In an embodiment, the masking pattern is formed of inorganic material.

An embodiment of the present disclosure provides a display device that includes: a base layer that includes a first base area and a second base area; a light-emitting-element layer disposed on the base layer, and that includes a light emitting element in the first base area and a pixel defining layer in the second base area; an organic insulating layer disposed on the light-emitting-element layer, wherein holes are formed in the organic insulating layer in the second base area; and touch electrodes disposed on the organic insulating layer.

In a display device in accordance with embodiments of the present disclosure, holes are formed between a cathode electrode and touch electrodes, so that the capacitance between the cathode electrode and the touch electrodes can be reduced. As a result, noise related to a touch can be reduced.

### BRIEF DESCRIPTION OF THE DRAWINGS

FIG. 1 illustrates a display device in accordance with embodiments of the present disclosure.

FIG. 2 illustrates a touch panel and a display panel of a display device of FIG. 1.

FIG. 3 illustrates a touch panel and a display panel of a display device in accordance with embodiments of the present disclosure.

FIGS. 4 and 5 illustrate examples of a width of a hole that depends on a resolution of a display device of FIG. 1.

FIG. 6 illustrates a display panel of a display device in accordance with embodiments of the present disclosure.

FIG. 7 is a flowchart of a method of fabricating a display device in accordance with embodiments of the present disclosure.

FIGS. 8 to 16 illustrate a method of fabricating a display device of FIG. 7.

FIGS. 17 to 18 illustrate a method of fabricating a display device in accordance with embodiments of the present disclosure.

FIG. 19 is a block diagram of an electronic device in accordance with embodiments of the present disclosure.

### DETAILED DESCRIPTION

Hereinafter, embodiments of the present disclosure will be described in detail with reference to the attached drawings. However, the present disclosure is not limited to embodiments set forth herein but may be embodied in other types.

Various embodiments will be described with reference to diagrams illustrating embodiments. As such, variations from the shapes of the illustrations that result from, for example, manufacturing techniques and/or tolerances, are to be expected. Therefore, embodiments disclosed herein should not be construed as limited to the particular illustrated shapes of regions, but are to include deviations in shapes that result from, for instance, manufacturing.

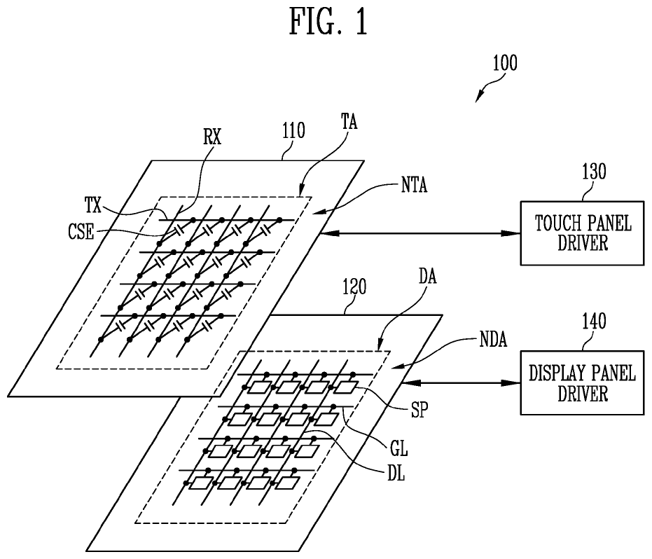

FIG. 1 illustrates a display device 100 in accordance with embodiments of the present disclosure.

Referring to FIG. 1, in an embodiment, the display device 100 includes a touch panel 110, a display panel 120, a touch panel driver 130, and a display panel driver 140.

FIG. 1 shows the touch panel 110 and the display panel 120 as being separated from each other, however, this is for convenience of illustration to functionally distinguish the touch panel 110 from the display panel 120 in the display device 100. For example, the touch panel 110 is formed is formed in an add-on type configuration through a separate process from the display panel 120, and the touch panel 110 and the display panel 120 are combined with each other, for example, by attaching the touch panel 110 to one surface of the display panel 120. For example, the touch panel 110 is formed along with the display panel 120 touch panel 110 is formed in an in-cell type configuration through a single process, such as a process of fabricating the display panel 120.

The touch panel 110 is disposed on one surface of the display panel 120. For example, the touch panel 110 is disposed on a surface of the display panel 120, such as an upper surface, from which an image is emitted. In an embodiment, the touch panel 110 is directly formed on at least one of two opposite surfaces of the display panel 120, or is formed in the display panel 120. For example, the touch panel 110 is directly formed on an outer surface of an upper substrate or a lower substrate, such as an upper surface of an upper substrate or a lower surface of a lower substrate, of the display panel 120, or is directly formed on an inner surface of the upper substrate, such as a lower surface of the upper substrate, or an inner surface of the lower substrate, such as an upper surface of the lower substrate.

The touch panel 110 includes a touch area TA that can detect touches, and a non-touch area NTA positioned outside the touch area TA, such as in a peripheral area or an edge area of the touch area TA. In an embodiment, the touch area TA corresponds to a display area DA of the display panel 120.

In an embodiment, the touch panel 110 is disposed so that at least one area thereof overlaps the display panel 120. For example, the touch area TA of the touch panel 110 is disposed on the display area DA of the display panel 120. In an embodiment, at least one electrode that detects touches is disposed in the touch area TA. The at least one electrode that detects touches includes a first touch electrode TX and a second touch electrode RX. The first touch electrode TX and the second touch electrode RX are disposed in the display area DA of the display panel 120.

Lines are disposed in the non-touch area NTA that electrically connect the at least one electrode in the touch area TA to the touch panel driver 130. For example, lines are disposed in the non-touch area NTA that electrically connect the first touch electrode TX and the second touch electrode RX to the touch panel driver 130. The non-touch area NTA corresponds to a non-display area NDA of the display panel 120.

The touch panel 110 includes at least one first touch electrode TX and at least one second touch electrode RX. For example, the touch panel 110 includes a first touch electrode TX and a second touch electrode RX that intersects the first touch electrode TX. In an embodiment, the first touch electrode TX extends in a first direction. The second touch electrode RX is insulated from the first touch electrode TX by an insulating layer and extends in a second direction that crosses the first direction. A capacitor CSE is formed between the first touch electrode TX and the second touch electrode RX. The capacitance between the first touch electrode TX and the second touch electrode RX changes when a touch occurs at or around the corresponding location. Therefore, the touch panel driver 130 can detect the touch by sensing a change in capacitance between the first touch electrode TX and the second touch electrode RX.

For example, embodiments of the present disclosure are not necessarily limited to specific shapes, sizes, and/or arrangement orientation of the first touch electrode TX and the second touch electrode RX.

The display panel 120 includes the display area DA in which an image can be displayed, and the non-display area NDA in which no image is displayed positioned outside the display area DA, for example, around an edge area or a peripheral area of the display area DA.

A gate line GL and a data line DL are disposed in the display area DA. Sub-pixels SP that are electrically connected to the gate line GL and the data line DL are disposed in the display area DA. Lines configured to supply various driving signals and/or power for driving the sub-pixels SP are disposed in the non-display area NDA.

However, embodiments of the present disclosure are not necessarily limited a specific type of display panel 120. For example, the display panel 120 is a self-emissive display panel. For example, the display panel 120 includes a plurality of light emitting elements. For instance, each light emitting element is an organic light emitting diode. For example, the light emitting element is an inorganic light emitting diode such as a micro light emitting diode (micro LED) or a quantum dot light emitting diode. For example, the light emitting element is formed of a combination of organic material and inorganic material. For instance, the display panel 120 is a non-emissive display panel such as a liquid crystal display (LCD) panel, an electro-phoretic display (EPD) panel, or an electro-wetting display (EWD) panel. When the display panel 120 is a non-emissive display panel, the display device 100 further includes a backlight unit that supplies light to the display panel 120.

The touch panel driver 130 is connected to the touch panel 110 and transmits a signal to the touch panel 110, or receives a signal from the touch panel 110. The touch panel driver 130 supplies a touch driving signal to the touch panel 110, and thereafter receives a touch sensing signal that corresponds to the touch driving signal from the touch panel 110 to detect a touch. For example, the touch panel driver 130 includes a touch driving signal transmitter and a touch sensing signal receiver. In an embodiment, the touch driving signal transmitter and the touch sensing signal receiver are integrated into a single integrated circuit (IC), but embodiments of the present disclosure are not necessarily limited thereto. In an embodiment, the touch panel driver 130, such as the touch driving signal transmitter, simultaneously (or sequentially) transmits touch driving signals to the plurality of first touch electrodes TX. The touch panel driver 130, such as the touch sensing signal receiver, receives a touch sensing signal from second sensing electrodes RX. The touch panel driver 130 receives a touch sensing signal from the touch panel 110, and processes the touch sensing signal through a signal processing process to detect a touch input status and/or touch coordinates.

The display panel driver 140 is connected to the display panel 120 and transmits a signal to the display panel 120, or receives a signal from the display panel 120. The display panel driver 140 supplies a gate signal to the gate line GL, and supplies a data voltage to the data line DL.

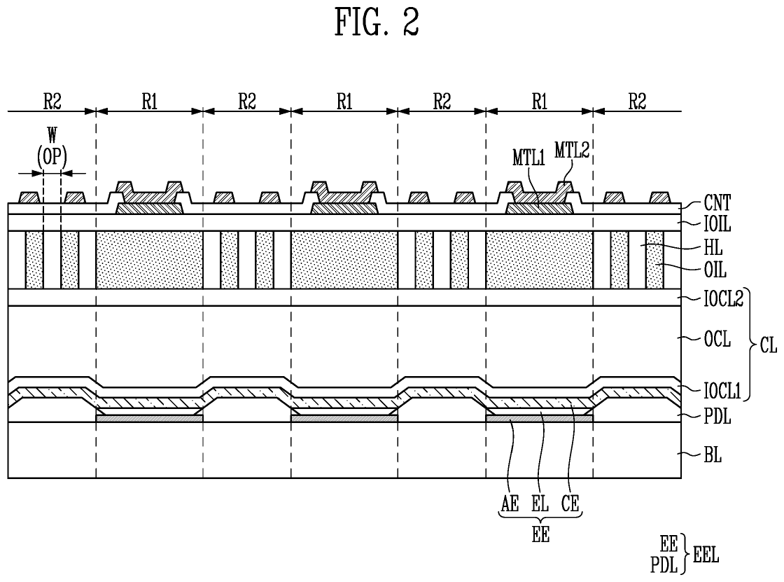

FIG. 2 illustrates an example of the touch panel 110 and the display panel 120 of the display device 100 of FIG. 1.

Referring to FIGS. 1 and 2, in an embodiment, the display device 100 includes a base layer BL, a light-emitting-element layer EEL, an encapsulation layer CL, an organic insulating layer OIL, an inorganic insulating layer IOIL, a touch insulating layer CNT, and touch electrodes TX and RX. The touch panel 110 includes the touch insulating layer CNT and the touch electrodes TX and RX. The display panel 120 includes the base layer BL and the light-emitting-element layer EEL.

The base layer BL includes a first area R1 and a second area R2. Light emitting elements EE are disposed on the base layer BL in the first area R1. For example, the first area R1 is an emission area, and the second area R2 is a non-emission area.

The base layer BL includes a substrate and a circuit element layer in which circuit elements are formed. For example, the substrate is one of a glass substrate, a metal substrate, or an organic/inorganic composite substrate, etc. For example, the sub-pixel SP includes a light emitting element EE and a pixel driving circuit that drives the light emitting element EE. The circuit element layer includes the pixel driving circuit.

The light-emitting-element layer EEL is disposed on the base layer BL, and includes the light emitting element EE in the first area R1. The light-emitting-element layer EEL includes the light emitting element EE and a pixel defining layer PDL. The light emitting element EE includes an anode electrode AE, an emission layer EL, and a cathode electrode CE. In an embodiment, the cathode electrode CE is formed in the first area R1 and the second area R2.

The anode electrode AE supplies holes to the emission layer EL. For example, the anode electrode AE includes a metal layer made of at least one of silver (Ag), magnesium (Mg), aluminum (Al), platinum (Pt), palladium (Pd), gold (Au), nickel (Ni), neodymium (Nd), iridium (Ir), chrome (Cr), or an alloy thereof, and/or indium tin oxide (ITO), indium zinc oxide (IZO), zinc oxide (ZnO), or indium tin zinc oxide (ITZO), etc.

The cathode electrode CE supplies electrons to the emission layer EL. For example, the cathode electrode CE includes at least one of silver, titanium (Ti), aluminum, molybdenum (Mo), or alloys of silver and magnesium (Ag: Mg), etc.

The emission layer EL is disposed on the anode electrode AE. The emission layer EL includes a first emission layer configured that displays a first color, a second emission layer that displays a second color, and a third emission layer that displays a third color. For example, the first color is red, the second color is green, and the third color is blue.

In the emission layer EL, holes received from the anode electrode (AE) and electrons received from the cathode electrode (CE) recombine with each other to form excitons. The excitons emit light as they decay. The emission layer EL includes materials that emit specific colors of light.

The pixel defining layer PDL is disposed in the second area R2. The pixel defining layer PDL includes an organic insulating layer that includes an organic material. The organic material includes one or more of an acryl resin, an epoxy resin, a phenolic resin, a polyamide resin, or a polyimide resin. The pixel defining layer PDL includes a light absorption material. The pixel defining layer PDL is coated with a light absorbent, thus absorbing external light. For example, the pixel defining layer PDL includes a carbon-based black pigment. However, embodiments of the present disclosure are not necessarily limited thereto. In an embodiment, the pixel defining layer PDL includes an opaque metal that has a high light absorptivity, such as at least one of chrome (Cr), molybdenum (Mo), an alloy (MoTi) of molybdenum and titanium, tungsten (W), vanadium (V), niobium (Nb), tantalum (Ta), manganese (Mn), cobalt (Co), or nickel (Ni).

The encapsulation layer CL is disposed on the light-emitting-element layer EEL. The encapsulation layer CL prevents penetration of external water or oxygen. The encapsulation layer CL includes a first inorganic encapsulation layer IOCL1, an organic encapsulation layer OCL, and a second inorganic encapsulation layer IOCL2. For example, the first inorganic encapsulation layer IOCL1 and the second inorganic encapsulation layer IOCL2 are formed of an inorganic material. The organic encapsulation layer OCL is formed of an organic material.

The organic insulating layer OIL is disposed on the encapsulation layer CL. Holes HL are formed in the organic insulating layer OIL. For example, the organic insulating layer OIL is formed of organic material.

The holes HL have an air trap structure. The air trap structure is a structure in which air is trapped. For example, the holes HL are blocked on a lower portion thereof by the second inorganic encapsulation layer IOCL2, and are blocked on an upper portion thereof by the inorganic insulating layer IOIL.

The permittivity of air is approximately 1, and air has a permittivity lower than that of the organic material. Therefore, as the holes HL with air trapped therein are positioned between the touch electrodes TX and RX and the cathode electrode CE, the capacitance between the touch electrodes TX and RX and the cathode electrode CE is reduced, and signal noise generated by a touch is reduced.

In an embodiment, the holes HL are formed in the second area R2. Light diffraction differs between air and organic material. If the holes HL are formed in the emission area, such as the first area R1, light emitted from the emission layer EL is refracted. Hence, the holes HL are formed in the non-emission area, such as the second area R2.

In an embodiment, the holes HL are formed through a photolithography process that uses a masking pattern formed of a photoresist.

The inorganic insulating layer IOIL is disposed on the organic insulating layer OIL. For example, the inorganic insulating layer IOIL is formed of an inorganic material.

During a process of forming the inorganic insulating layer IOIL on the organic insulating layer OIL, the inorganic insulating layer IOIL is deposited onto the holes HL of the organic insulating layer OIL. If the size of an opening OP of each hole HL is sufficiently small, the upper portions of the holes HL are blocked during the process of forming the inorganic insulating layer IOIL. For example, a width of each of the holes HL is about 1 μm or less.

The touch electrodes are formed of first conductive patterns MTL1 and second conductive patterns MTL2 that are disposed on the inorganic insulating layer IOIL.

Each of the first conductive pattern MTL1 and the second conductive pattern MTL2 includes metal or a transparent conductive layer. The metal is at least one of aluminum, titanium, copper, molybdenum, silver, or an alloy thereof. The transparent conductive layer includes a transparent conductive oxide such as at least one of indium tin oxide (ITO), indium zinc oxide (IZO), zinc oxide (ZnO), or indium tin zinc oxide (ITZO), a conductive polymer such as PEDOT, metal nanowires, or graphene, etc.

The touch insulating layer CNT includes an organic insulating layer that includes an organic material, or an inorganic insulating layer that includes an inorganic material. Some of the second conductive patterns MTL2 are electrically connected to the first conductive patterns MTL1 through contact holes that pass through the touch insulating layer CNT.

The first conductive patterns MTL1 electrically connect some of the second conductive patterns MTL2. In an embodiment, a first group of the second conductive patterns MTL2 that are connected by the first conductive patterns MTL1 forms the first touch electrode TX, and a second group of the second conductive patterns MTL2 forms the second touch electrode RX. In an embodiment, the first group of the second conductive patterns MTL2 that are connected by the first conductive patterns MTL1 forms the second touch electrode RX, and the second group of the second conductive patterns MTL2 forms the first touch electrode TX.

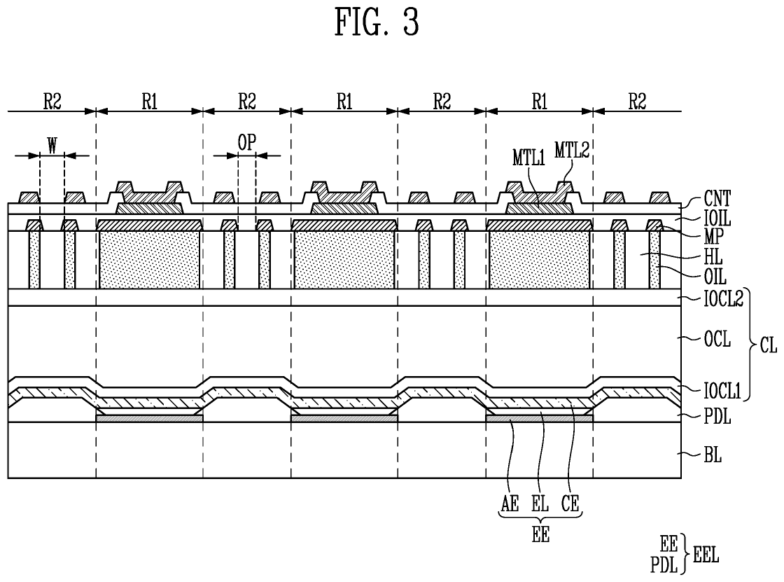

FIG. 3 illustrates the touch panel 110 and the display panel 120 of a display device in accordance with embodiments of the present disclosure.

A display device configuration in accordance with an embodiments is substantially the same as that of a display device of FIG. 1, other than a masking pattern MP and holes HL; therefore, identical or similar components may be denoted by the same reference numerals and symbols, and redundant explanation thereof may be omitted.

Referring to FIGS. 1 and 3, in an embodiment, the masking pattern MP is disposed between the organic insulating layer OIL and the inorganic insulating layer IOIL. The masking pattern MP is formed of an inorganic material. For example, the masking pattern MP is formed of indium zinc oxide (IZO).

The masking pattern MP is formed on the organic insulating layer OIL and patterns the holes HL. The holes HL can be formed in the organic insulating layer OIL through an etching process. The masking pattern MP functions as a hard mask, and substantially maintains its original form during a process of etching the organic insulating layer OIL. Therefore, while the masking pattern MP is maintained, the organic insulating layer OIL is continuously etched. For example, as shown in FIG. 3, not only an area of the organic insulating layer OIL exposed by the masking pattern MP may be etched, but also a portion of an area where the organic insulating layer OIL overlaps the masking pattern MP may be etched.

As the width W of each of the holes HL increases, the capacitance between the touch electrodes TX and RX and the cathode electrode CE is reduced. For example, if the size of the opening OP of each of the holes HL increases, the upper portions of the holes HL are not blocked during the process of forming the inorganic insulating layer IOIL. Therefore, by utilizing the inorganic masking pattern MP, the display device secures wider holes HL than those formed through a photolithography process, and maintains the size of the opening OP of each of the holes HL.

For example, the size of the opening OP of each of the holes HL corresponds to a size of the exposed portion of the inorganic insulating layer IOIL.

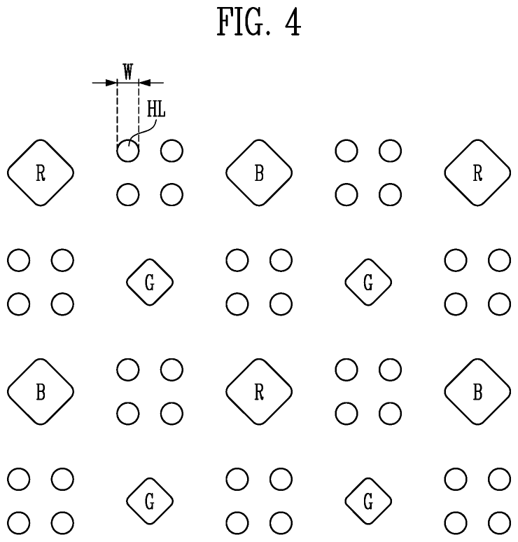

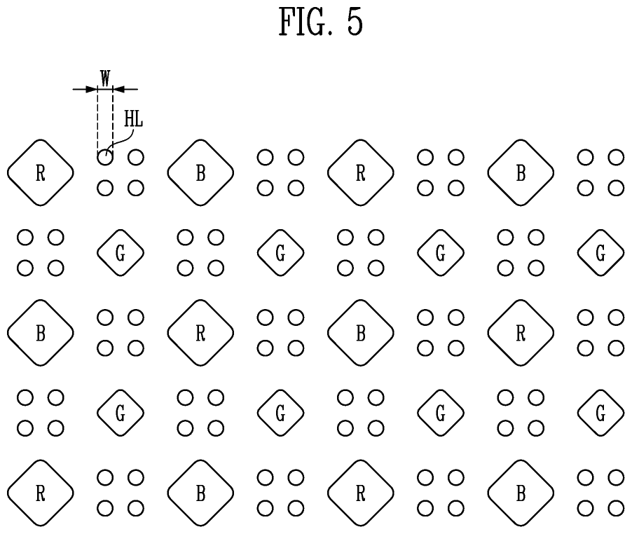

FIGS. 4 and 5 illustrate examples of a width W of each of the holes HL that depends on a resolution of the display device 100 of FIG. 1.

Referring to FIGS. 4 and 5, in an embodiment, the light emitting element EE includes a first light emitting element R that displays a first color, a second light emitting element G that displays a second color, and a third light emitting element B that displays a third color. However, embodiments of the present disclosure are not necessarily limited to such a pixel structure.

The holes HL are positioned in the non-emission area where the light emitting elements R, G, and B are not disposed. As the resolution of the display device is increased, the density of the light emitting elements R, G, and B increases. For example, as the resolution of the display device increases, the size of the non-emission area decreases. Hence, the width W of each of the holes HL is decreased as the resolution increases. For example, as illustrated in FIGS. 4 and 5, in a display device of FIG. 5, which has a resolution higher than that of FIG. 4, the width W of each of the holes HL is narrower.

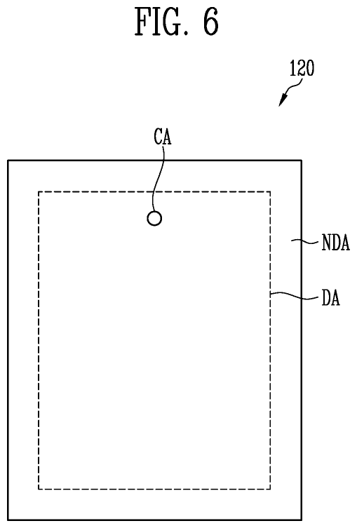

FIG. 6 illustrates the display panel 120 of a display device in accordance with embodiments of the present disclosure.

A display device configuration in accordance with an embodiment is substantially the same as that of FIG. 1, except for a camera area CA; therefore, identical or similar components may be denoted by the same reference numerals and symbols, and redundant explanations thereof may be omitted.

Referring to FIGS. 1, 2, and 6, in an embodiment, the display device 100 includes a camera area CA. An optical module is disposed under the camera area CA. The optical module utilizes optics. For example, the optical module includes at least one of a camera module, an iris recognition module, an optical fingerprint recognition module, or an infrared module, etc.

As the resolution of the display device 100 is increased, the size of the non-emission area decreases. Hence, the width W of each of the holes HL decreases as the resolution increases. Therefore, compared to a first display area, such as the camera area CA, that has a first resolution, the width W of each of the holes HL is in a second display area DA that has a second resolution higher than the first resolution is less than the width W of each of the holes HL is in the first display area.

In an embodiment, the camera area CA has been provided as an example of an area with a different resolution, but embodiments of the present disclosure are not necessarily limited thereto. For example, in areas that have resolutions that differ from that of the camera area CA, the width of each of the holes HL differs.

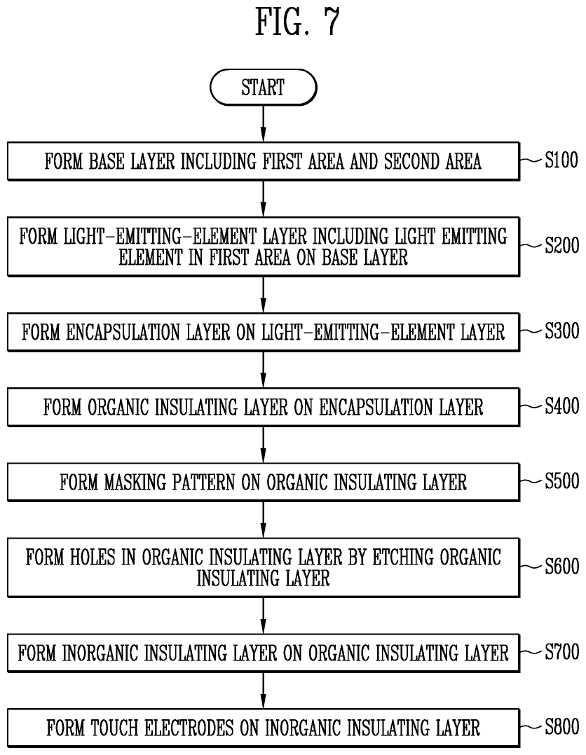

FIG. 7 is a flowchart of a method of fabricating a display device in accordance with embodiments of the present disclosure.

Referring to FIG. 7, in an embodiment, the method of fabricating the display device includes a step S100 of forming a base layer that includes a first area and a second area, a step S200 of forming a light-emitting-element layer that includes a light emitting element in the first area of the base layer, a step S300 of forming an encapsulation layer on the light-emitting-element layer, a step S400 of forming an organic insulating layer on an encapsulation layer, a step S500 of forming a masking pattern on the organic insulating layer, a step S600 of forming holes in the organic insulating layer by etching the organic insulating layer, a step S700 of forming an inorganic insulating layer on the organic insulating layer, and a step S800 of forming touch electrodes on the inorganic insulating layer.

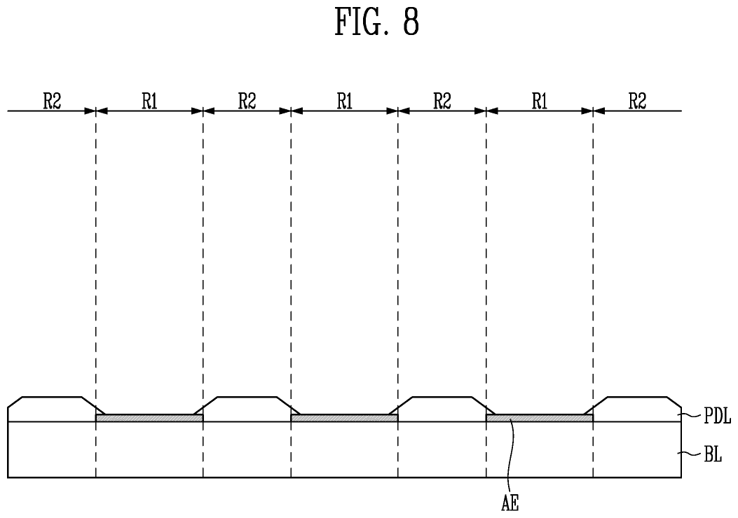

Hereinafter, a method of fabricating a display device will be described in detail with reference to FIGS. 8 to 16.

FIGS. 8 to 16 illustrating an example of a method of FIG. 7 of fabricating the display device.

Referring to FIG. 8, in an embodiment, the anode electrode AE is formed in the first area R1 on the base layer BL. The pixel defining layer PDL is formed in the second area R2 on the base layer BL.

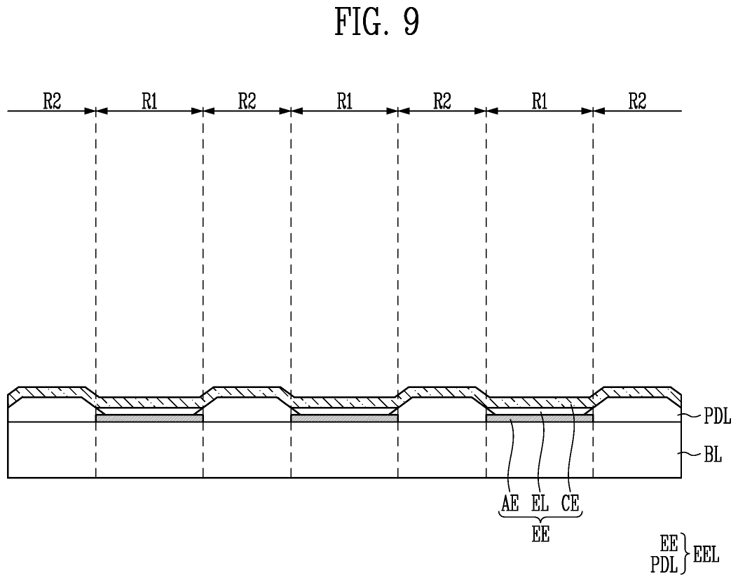

Referring to FIG. 9, in an embodiment, the emission layer EL is formed on the cathode electrode CE. The cathode electrode CE is formed that covers the pixel defining layer PDL and the emission layer EL.

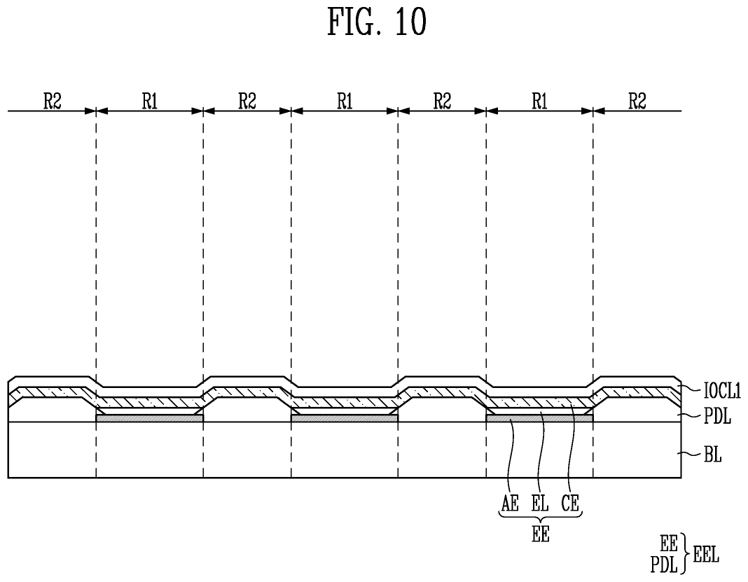

Referring to FIG. 10, in an embodiment, the first inorganic encapsulation layer IOCL1 is formed on the cathode electrode CE. The first inorganic encapsulation layer IOCL1 covers the cathode electrode CE.

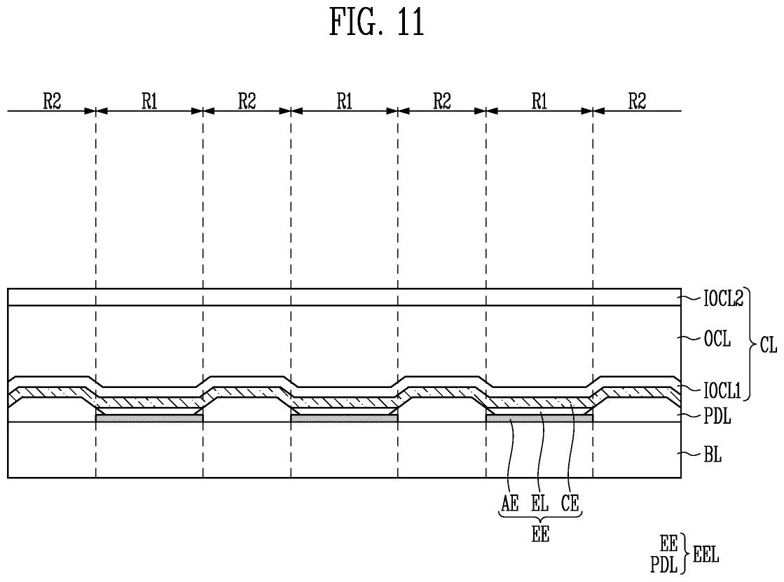

Referring to FIG. 11, in an embodiment, the organic encapsulation layer OCL is formed on the first inorganic encapsulation layer IOCL1. The second inorganic encapsulation layer IOCL2 is formed on the organic encapsulation layer OCL.

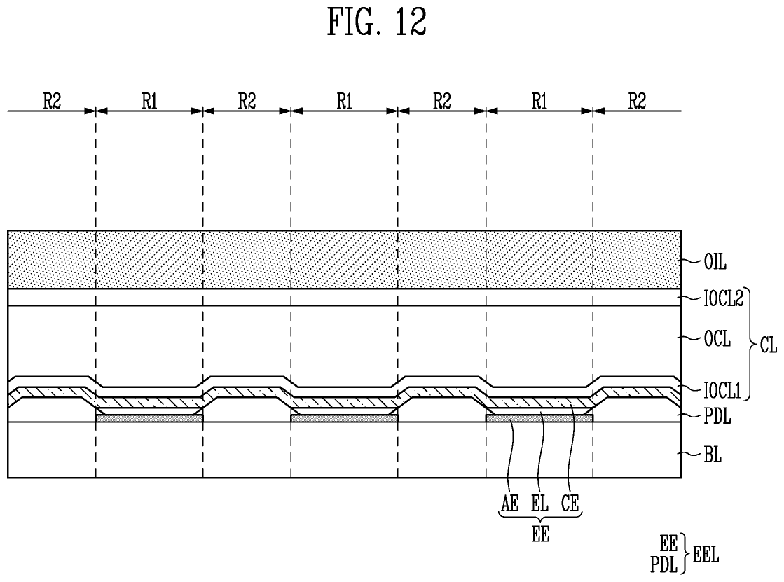

Referring to FIG. 12, in an embodiment, the organic insulating layer OIL is formed on the encapsulation layer CL. For example, the organic insulating layer OIL is formed on the second inorganic encapsulation layer IOCL2.

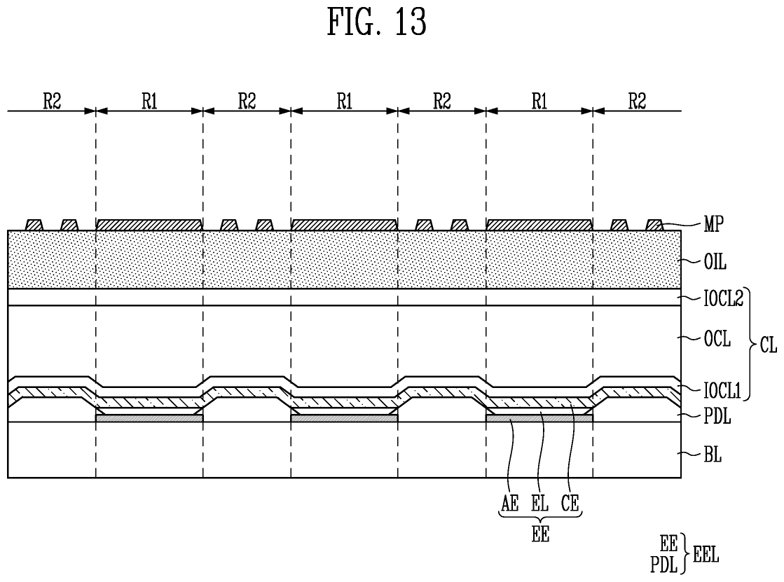

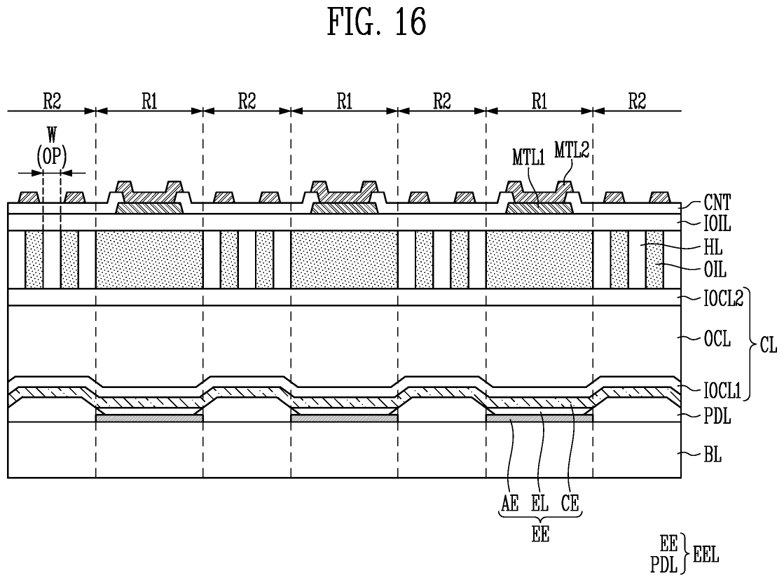

Referring to FIG. 13, in an embodiment, the masking pattern MP is formed on the organic insulating layer OIL. The masking pattern MP is formed on the organic insulating layer OIL to pattern the holes (refer to HL of FIG. 16).

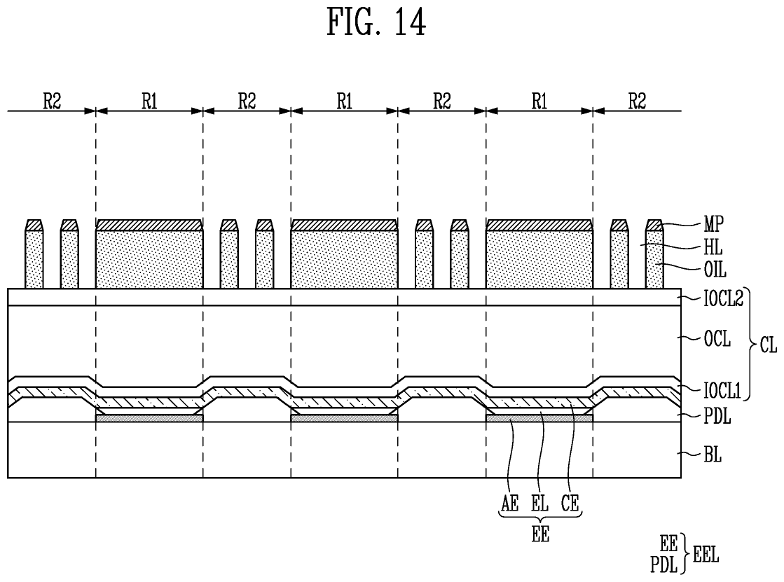

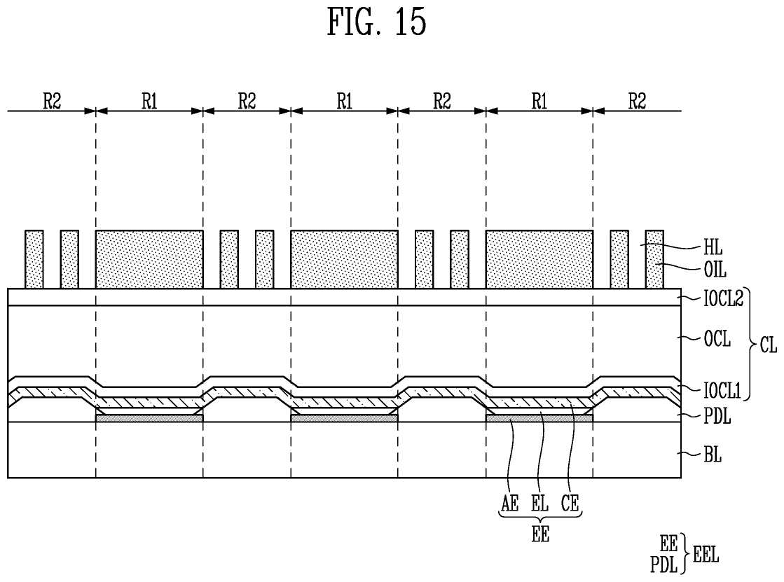

Referring to FIGS. 14 and 15, in an embodiment, the organic insulating layer OIL is etched through a photolithography process to form the holes HL. Thereafter, the masking pattern MP is removed. In an embodiment, the holes HL are formed in the second area R2.

Referring to FIG. 16, in an embodiment, the inorganic insulating layer IOIL is formed on the organic insulating layer OIL. The inorganic insulating layer IOIL covers an upper portion of each of the holes HL of the organic insulating layer OIL. As a result, the holes HL have an air trap structure.

The touch insulating layer CNT is formed on the inorganic insulating layer IOIL. The touch insulating layer CNT and the first conductive patterns MTL1 are formed on the inorganic insulating layer IOIL. Some of the second conductive patterns MTL2 are electrically connected to the first conductive patterns MTL1 through contact holes that pass through the touch insulating layer CNT.

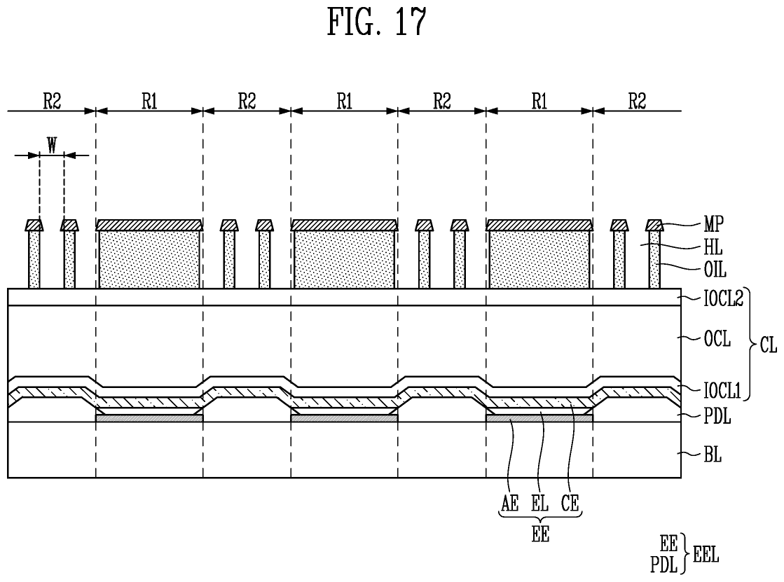

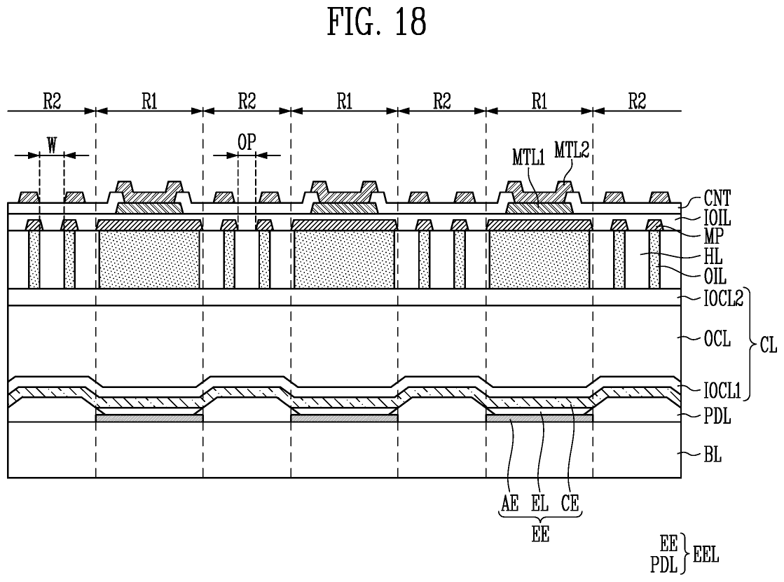

FIGS. 17 to 18 illustrate a method of fabricating a display device in accordance with embodiments of the present disclosure.

A method of fabricating a display device in accordance with an embodiment is substantially the same as a method of FIG. 7 of fabricating a display device, except for the masking pattern MP; therefore, identical or similar components may be denoted by the same reference numerals and symbols, and redundant explanation thereof may be omitted.

Referring to FIGS. 17 and 18, in an embodiment, the masking pattern MP is formed on the organic insulating layer OIL. For example, the masking pattern MP is formed of an inorganic material. For example, the masking pattern MP is formed of indium zinc oxide (IZO).

The masking pattern MP is formed on the organic insulating layer OIL to pattern the holes HL. The holes HL are formed in the organic insulating layer OIL through an etching process. The inorganic insulating layer IOIL is disposed on the masking pattern MP.

The inorganic masking pattern MP functions as a hard mask, and substantially maintains its original form during a process of etching the organic insulating layer OIL Therefore, while the masking pattern MP is maintained, the organic insulating layer OIL is continuously etched. For example, a portion of the organic insulating layer OIL exposed by the masking pattern MP is etched.

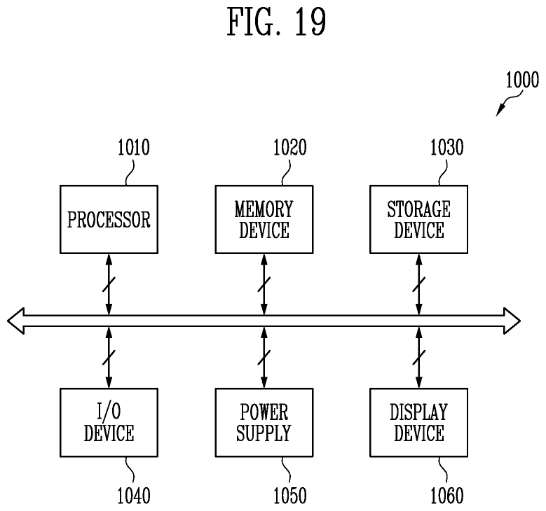

FIG. 19 is a block diagram of an electronic device 1000 in accordance with embodiments of the present disclosure.

Referring to FIG. 19, in an embodiment, the electronic device 1000 includes a processor 1010, a memory device 1020, a storage device 1030, an input/output (I/O) device 1040, a power supply 1050, and a display device 1060. The display device 1060 is the display device of FIG. 1. The electronic device 1000 can include additional ports for communication with a video card, a sound card, a memory card, a USB device, or other systems. In an embodiment, the electronic device 1000 is implemented as one of a smartphone, a television, a cellular phone, a video phone, a smartpad, a smartwatch, a tablet PC, a navigation device for vehicles, a computer monitor, a laptop computer, or a head-mounted display device, etc.

The processor 1010 performs specific calculations or tasks. In an embodiment, the processor 1010 is one of a micro processor, a central processing unit, or an application processor, etc. The processor 1010 is connected to other components through one of an address bus, a control bus, a data bus, etc. In an embodiment, the processor 1010 is connected to an expansion bus such as a peripheral component interconnect (PCI) bus. The memory device 1020 stores data needed to perform the operations of the electronic device 1000. For example, the memory device 1020 is one or more of a non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, or a ferroelectric random access memory (FRAM) device, and/or a volatile memory device such as a dynamic random access memory (DRAM) device, a static random access memory (SRAM) device, a mobile DRAM device, etc.

The storage device 1030 includes one or more of a solid state drive (SSD), a hard disk drive (HDD), a CD-ROM, etc.

The I/O device 1040 includes input devices such as a keyboard, a keypad, a touchpad, a touch screen, and/or a mouse, and output devices such as a speaker and/or a printer. In an embodiment, the display device 1060 is included in the I/O device 1040.

The power supply 1050 supplies power needed to perform the operations of the electronic device 1000. For example, the power supply 1050 is a power management integrated circuit (PMIC).

The display device 1060 displays an image that corresponds to visual information of the electronic device 1000. The display device 1060 is one of an organic light emitting display device or a quantum dot light emitting display device, but is not necessarily limited thereto. The display device 1060 is connected to other components through the buses or other communication links.

Embodiments of the present disclosure can be incorporated into a display device and an electronic device that includes the display device. For example, embodiments of the present disclosure can be incorporated into digital TVs, 3D TVs, cellular phones, smartphones, tablet computers, VR devices, PCs, home appliances, laptop computers, PDAs, portable media players (PMPs), digital cameras, music players, portable game consoles, navigation devices, etc.

While embodiments have been described above, those skilled in the art will appreciate that various modifications, additions and substitutions are possible, without departing from the scope and spirit of the present disclosure as claimed in the appended claims.

What is claimed is:

1. A display device, comprising:
a base layer that includes a first area and a second area;
a light-emitting-element layer disposed on the base layer, and that includes a light emitting element in the first area;
an encapsulation layer disposed on the light-emitting-element layer;
an organic insulating layer disposed on the encapsulation layer, wherein holes are formed in the organic insulating layer;
an inorganic insulating layer disposed on the organic insulating layer; and
touch electrodes disposed on the inorganic insulating layer.

2. The display device according to claim 1, wherein the holes are formed in the second area.

3. The display device according to claim 1, wherein the holes have an air trap structure.

4. The display device according to claim 1, wherein the light-emitting-element layer further includes a pixel defining layer in the second area.

5. The display device according to claim 1, wherein each of the holes has a width of about 1 μm or less.

6. The display device according to claim 1, wherein a width of each of the holes decreases as a resolution of the display device increases.

7. The display device according to claim 1, wherein a width of each of the holes in a second display area that has a second resolution is less than a width of each of the holes in first display area that has a first resolution that is less than the second resolution.

8. The display device according to claim 1, further comprising a masking pattern disposed between the organic insulating layer and the inorganic insulating layer.

9. The display device according to claim 8, wherein the masking pattern overlaps a portion of at least one of the holes.

10. The display device according to claim 8, wherein the masking pattern is formed of inorganic material.

11. The display device according to claim 1,
wherein the touch electrodes are formed of first conductive patterns and second conductive patterns that are disposed on the inorganic insulating layer, and
wherein the first conductive patterns electrically connect some of the second conductive patterns.

12. A method of fabricating a display device, comprising:
forming a base layer that includes a first area and a second area;
forming a light-emitting-element layer on the base layer wherein the light-emitting-element layer includes a light emitting element in the first area;
forming an encapsulation layer on the light-emitting-element layer;
forming an organic insulating layer on the encapsulation layer;
forming a masking pattern on the organic insulating layer;
forming holes in the organic insulating layer by etching the organic insulating layer;
forming an inorganic insulating layer on the organic insulating layer; and
forming touch electrodes on the inorganic insulating layer.

13. The method according to claim 12, wherein the holes are formed in the second area.

14. The method according to claim 12, wherein the inorganic insulating layer covers an upper portion of each of the holes of the organic insulating layer.

15. The method according to claim 12, wherein the light-emitting-element layer further includes a pixel defining layer in the second area.

16. The method according to claim 12, wherein each of the holes has a width of about 1 μm or less.

17. The method according to claim 12, wherein the masking pattern is formed of a photoresist.

18. The method according to claim 12, wherein the organic insulating layer is etched on a portion of an area where the organic insulating layer overlaps the masking pattern.

19. The method according to claim 12, wherein the masking pattern is formed of an inorganic material.

20. A display device, comprising:
a base layer that includes a first area and a second area;
a light-emitting-element layer disposed on the base layer, and that includes a light emitting element in the first area and a pixel defining layer in the second area;
an organic insulating layer disposed on the light-emitting-element layer, wherein holes are formed in the organic insulating layer in the second area; and
touch electrodes disposed on the organic insulating layer.
